(19) United States
(12) Patent Application Publication
(10) Pub. No.: US 2026/0213120 A1
(43) Pub. Date: Jul. 23, 2026

(54) NANO-PROBE MEASUREMENT SYSTEM

(71) Applicant: Samsung Electronics Co., Ltd., Suwon-si (KR)

(72) Inventors: Gwang-Hyeon Nam, Suwon-si (KR); JONGCHUL KIM, Suwon-si (KR); YOUNGHOON SOHN, Suwon-si (KR); HYUNGKEUN YOO, Suwon-si (KR); YONG DEOK JEONG, Suwon-si (KR)

(21) Appl. No.: 19/439,606

(22) Filed: Jan. 5, 2026

(30) Foreign Application Priority Data
Jan. 22, 2025 (KR) 10-2025-0009754

(51) Int. Cl. H01J 37/20; H01J 37/141; H01J 37/244; H01J 37/28

(52) U.S. Cl. CPC H01J 37/20; H01J 37/141; H01J 37/244; H01J 37/28; H01J 2237/1205; H01J 2237/2448; H01J 2237/24564

(57) ABSTRACT

A measurement system includes a chamber, a multi-electron beam generator coupled with the chamber and configured to generate a plurality of electron beams, an electron beam column coupled with a lower end of the multi-electron beam generator and configured to guide the electron beams, nano-probes placed below the electron beam column in the chamber, and a source measure device electrically connected to the nano-probes. Each of the nano-probes includes a probe arm and a probe pin connected to one end of the probe arm. The electron beam column and the probe arms are configured to guide the electron beams to the probe pins.

### CROSS-REFERENCE TO RELATED APPLICATION(S)

This U.S. non-provisional patent application claims priority under 35 U.S.C. § 119 of Korean Patent Application No. 10-2025-0009754, filed on Jan. 22, 2025, the contents of which are hereby incorporated by reference in its entirety.

### BACKGROUND

Embodiments of the present disclosure described herein relate to a measurement system. More particularly, embodiments of the present disclosure described herein relate to a measurement system capable of calculating positions of probe pins of nano-probes.

A semiconductor device includes an integrated circuit including metal-oxide-semiconductor field-effect transistors (MOSFETs). The electrical properties of the semiconductor device are measured using a variety of methods. As an example, the electrical properties of the semiconductor device are measured by using probe pins. For instance, the probe pins are brought into contact with terminals of the semiconductor device and measurement currents are applied to the semiconductor device or components in the semiconductor device through the probe pins to measure the electrical properties of the semiconductor device.

As semiconductor devices become more miniaturized, the probe pins are also being made smaller. As a result, the probe pins are more likely to fail to be positioned accurately on probing points. Accordingly, various measurement methods are being studied to calculate positions of the probe pins.

### SUMMARY

Embodiments of the present disclosure provide a measurement system capable of more accurately identifying positions of probe pins.

According to an embodiment, a measurement system may include a chamber, a multi-electron beam generator coupled with the chamber and configured to generate a plurality of electron beams, an electron beam column coupled with a lower end of the multi-electron beam generator and configured to guide the electron beams, nano-probes placed below the electron beam column in the chamber, and a source measure device electrically connected to the nano-probes. Each of the nano-probes may include a probe arm and a probe pin connected to one end of the probe arm. The electron beam column and the probe arms may be configured to guide the electron beams to the probe pins.
According to an embodiment, a measurement system may include a chamber, a multi-electron beam generator coupled with the chamber and generating a plurality of electron beams, an electron beam column coupled with a lower end of the multi-electron beam generator, guiding the electron beams, and including a plurality of micro-lenses configured to control irradiation points of the electron beams, respectively, nano-probes placed below the electron beam column in the chamber, and a source measure device electrically connected to the nano-probes. Each of the nano-probes may include a probe arm and a probe pin connected to one end of the probe arm. The electron beam column and the probe arms may be configured to guide the electron beams to the probe pins, and the source measure device may be configured to measure currents generated in the probe pins by the electron beams.
According to an embodiment, a measurement system may include a chamber, a plurality of electron beam generators coupled with the chamber, generating a plurality of electron beams, respectively, and spaced apart from each other, an electron beam column coupled with lower ends of the electron beam generators and configured to guide the electron beams, nano-probes placed below the electron beam column in the chamber, and a source measure device electrically connected to the nano-probes. Each of the nano-probes may include a probe arm and a probe pin connected to one end of the probe arm. The electron beam column and the probe arms may be configured to guide the electron beams to the probe pins, and the source measure device may be configured to measure currents generated in the probe pins by the electron beams.
According to an embodiment, a method of operating a measurement system may include generating a plurality of electron beams using a multi-electron beam generator, identifying positions of probe pins, measuring reference values for each position of the probe pins, guiding the electron beams to the probe pins using an electron beam column, moving the probe pins, measuring currents of the probe pins using a source measure device, calculating positions of probe tips of the probe pins using a control system, comparing the positions of the probe tips to positions of corresponding probing points, and allowing the probe tips to come in contact with the probing points, respectively, when the probe tips respectively overlap the corresponding probing points vertically.
In an embodiment, the electron beam column may include micro-lenses, and the guiding of the electron beams to the probe pins using the electron beam column may include guiding irradiation points of the electron beams to the probe pins through the micro-lenses, respectively.
In an embodiment, the multi-electron beam generator may include an electron gun and a split plate, which is provided with a plurality of apertures defined therethrough. In this case, the generating of the electron beams using the multi-electron beam generator may include irradiating a bulk electron beam onto the split plate using the electron gun and converting the bulk electron beam into the electron beams through the apertures.
In an embodiment, each of the probe pins may be connected to one end of the probe arm that moves the probe pin horizontally and vertically, and the moving of the probe pins may include moving the probe pins three-dimensionally using the movement of the probe arms.
In an embodiment, the moving of the probe pins, the measuring of currents of the probe pins using the source measure device, and the calculating of the positions of the probe tips of the probe pins using the control system may be repeatedly performed until the probe tips vertically overlap the corresponding probing points, respectively.
In an embodiment, the identifying of the positions of the probe pins may include rotating the irradiation point of at least one of the electron beams using the electron beam column to identify the positions of the probe pins.
In an embodiment, the measuring of the reference values for each position of the probe pins may include scanning a corresponding probe pin among the probe pins using each of the electron beams to measure the current values for each position of the corresponding probe pin. The current values for each position may be the reference values for each position.
In an embodiment, the method of operating the measurement system may further include loading a substrate before the generating of the electron beams using the multi-electron beam generator.
In an embodiment, the loading of the substrate may include loading the substrate on a chuck and placing an inspection target of the substrate below the electron beam column using a moving stage.
In an embodiment, the method of operating the measurement system may further include irradiating the electron beams onto the inspection target, detecting secondary electrons emitted from the inspection target using an electron detector, obtaining the image of the inspection target from the detected secondary electrons, and obtaining positional coordinates of the probing points in the inspection target from the obtained image.

According to the above, the multi-electron beam generator may generate multiple electron beams, and the electron beam column may guide the electron beams. Further, the electron beam column may guide the electron beams to be irradiated onto the probe pins of the nano-probes. In addition, the source measure device may measure the currents generated in the probe pins, and the control system may calculate the positions of the probe pins from the measured currents. Accordingly, the probing points of the probe pins may be precisely identified.

According to the above, the electron beams are respectively irradiated onto the probe pins, thus, changes in the currents according to the movement of the probe pins may be monitored in real time. The control system may calculate the positions of the probe pins from the measured currents. Accordingly, the control system may calculate the positions of the probe pins real time.

### BRIEF DESCRIPTION OF THE FIGURES

The above and other objects and features of the present disclosure will become

apparent by describing in detail embodiments thereof with reference to the accompanying drawings.

FIG. 1 is a schematic view illustrating a measurement system according to an embodiment of the present disclosure;

FIG. 2 is a plan view schematically illustrating nano-probes, a source measure device, and a control system according to an embodiment of the present disclosure;

FIG. 3 is an enlarged plan view illustrating an area S1 of FIG. 2;

FIG. 4 is a perspective view schematically illustrating a multi-electron beam generator and an electron beam column according to an embodiment of the present disclosure;

FIG. 5 is a plan view illustrating a trajectory of an electron beam irradiated onto probe pins while rotating according to an embodiment of the present disclosure;

FIG. 6 is a perspective view illustrating multiple electron beams respectively irradiated onto probe pins according to an embodiment of the present disclosure;

FIG. 7 is a perspective view illustrating multiple electron beams irradiated onto an inspection target according to an embodiment of the present disclosure;

FIG. 8 is a cross-sectional view illustrating probe pins that are in contact with probing points according to an embodiment of the present disclosure;

FIG. 9 is a flowchart illustrating a method of operating a measurement system according to an embodiment of the present disclosure;

FIG. 10 is a flowchart illustrating an operation (S130) of FIG. 9;

FIG. 11 is a view illustrating currents flowing through probe tips when an electron beam is irradiated while rotating according to an embodiment of the present disclosure;

FIG. 12 is a view illustrating reference values for each position of a probe pin according to an embodiment of the present disclosure;

FIG. 13 is a view illustrating changes in current as a function of movement of a probe pin according to an embodiment of the present disclosure; and

FIG. 14 is a schematic view illustrating a measurement system according to an embodiment of the present disclosure.

### DETAILED DESCRIPTION

Hereinafter, embodiments of the present disclosure will be described with reference to accompanying drawings.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

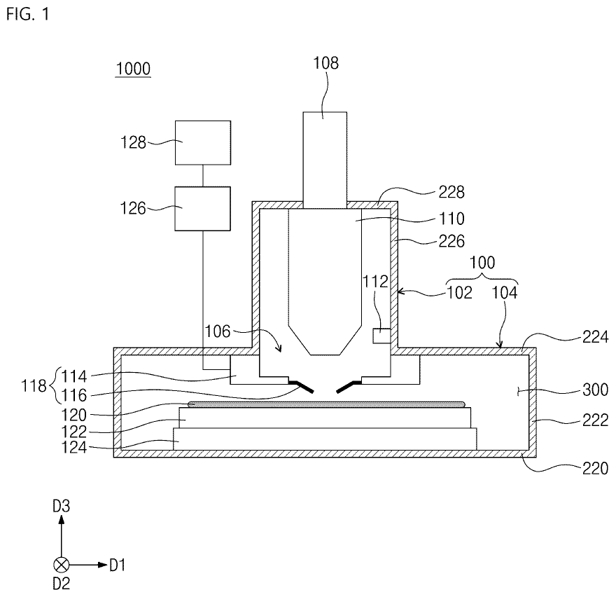

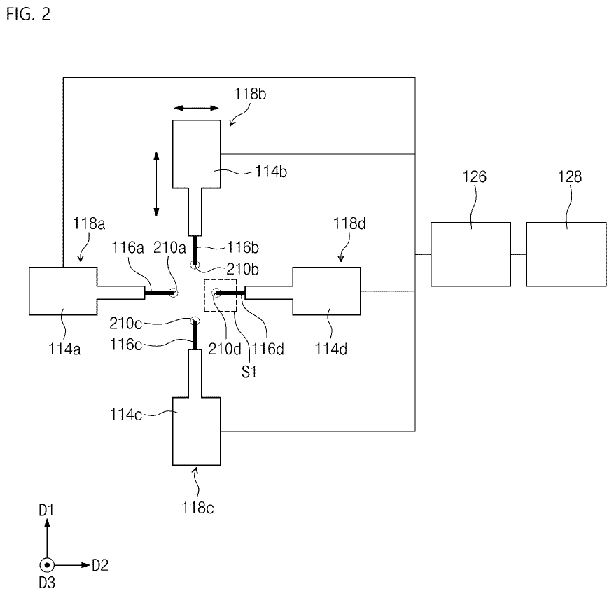

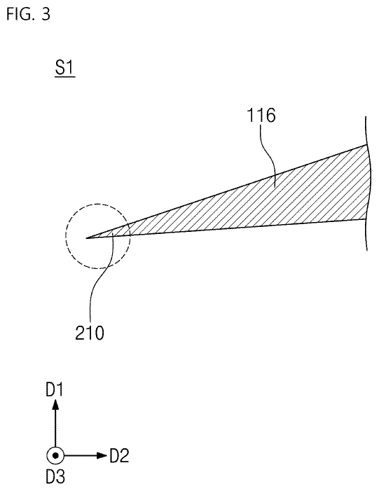

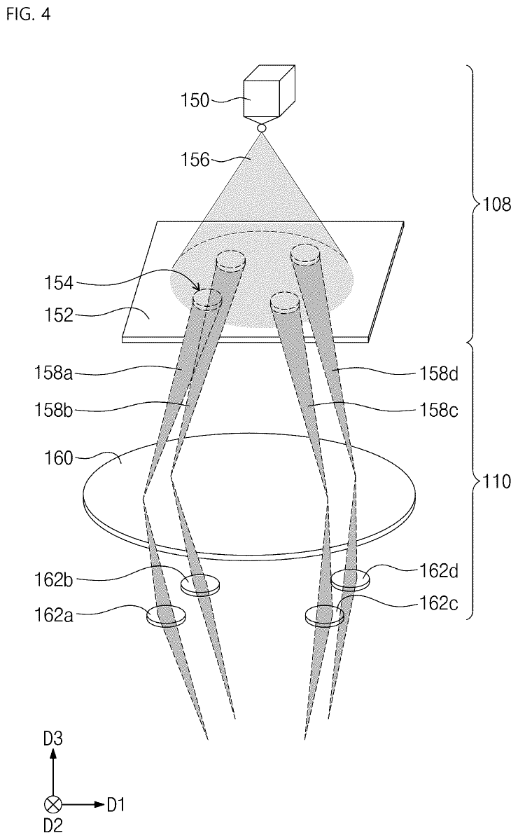

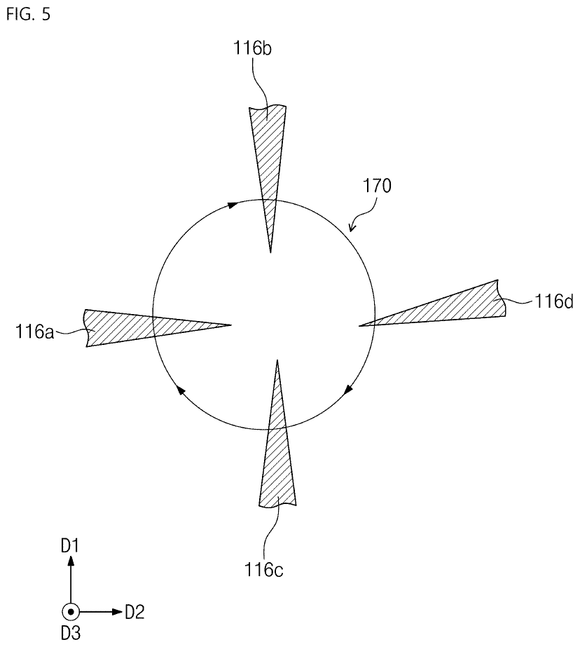

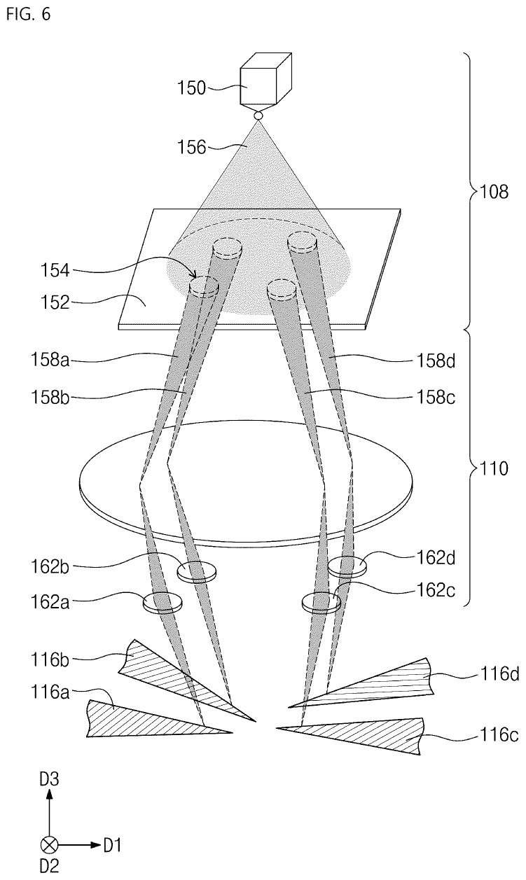

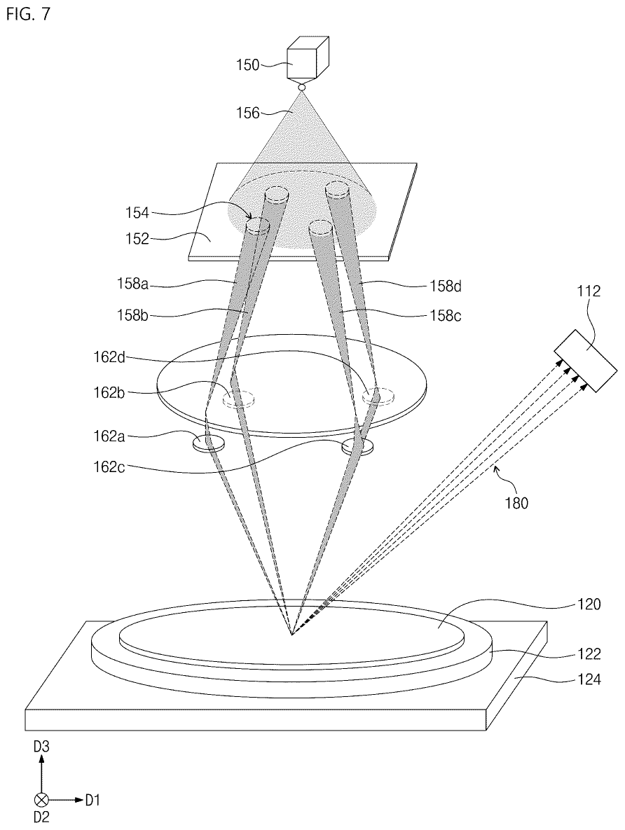

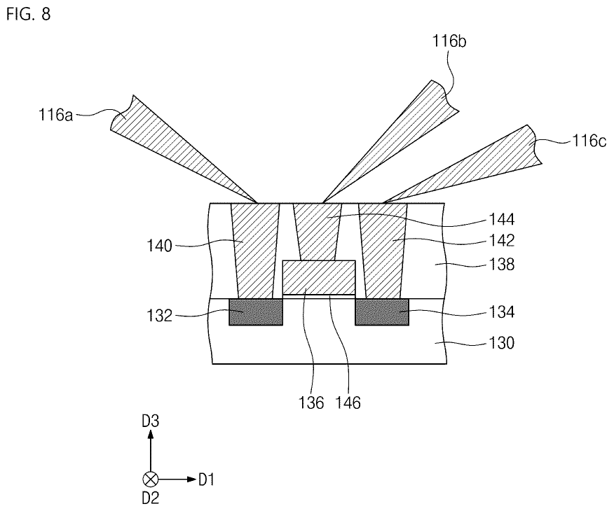

FIG. 1 is a schematic view illustrating a measurement system according to an embodiment of the present disclosure. FIG. 2 is a plan view schematically illustrating nano-probes, a source measure device, and a control system according to an embodiment of the present disclosure. FIG. 3 is an enlarged plan view illustrating an area S1 of FIG. 2. FIG. 4 is a perspective view schematically illustrating a multi-electron beam generator and an electron beam column according to an embodiment of the present disclosure. FIG. 5 is a plan view illustrating a trajectory of an electron beam irradiated onto probe pins while rotating according to an embodiment of the present disclosure. FIG. 6 is a perspective view illustrating multiple electron beams respectively irradiated onto probe pins according to an embodiment of the present disclosure. FIG. 7 is a perspective view illustrating multiple electron beams irradiated onto an inspection target according to an embodiment of the present disclosure. FIG. 8 is a cross-sectional view illustrating probe pins that are in contact with probing points according to an embodiment of the present disclosure.

Referring to FIGS. 1 to 8, the measurement system 1000 may include a chamber 100, the multi-electron beam generator 108, the electron beam column 110, an electron detector 112, the nano-probes 118a to 118d, a chuck 122, a moving stage 124, a source measure device 126, and the control system 128.

The chamber 100 may include an upper chamber 102 and a lower chamber 104. The lower chamber 104 may include a first bottom portion 220, a first wall portion 222 extending upward from an edge of the first bottom portion 220, and a first ceiling portion 224 (referred to as a ceiling portion of the lower chamber) overlapping the first bottom portion 220. In addition, an opening 106 may be defined through a center of the first ceiling portion 224 of the lower chamber 104. The upper chamber 102 may be placed on the lower chamber 104 and may be coupled with the first ceiling portion 224 of the lower chamber 104. The upper chamber 102 may include a second wall portion 226 extending upward from the coupled portion between the upper chamber 102 and the first ceiling portion 224 and a second ceiling portion 228 overlapping the first bottom portion 220. For instance, the upper chamber 102 may not include a bottom portion. The second ceiling portion 228 may be placed at a position higher than a position of the first ceiling portion 224. An inner space of the upper chamber 102 may be connected to an inner space of the lower chamber 104 through the opening 106. The first bottom portion 220, the first wall portion 222, the first ceiling portion 224, the second wall portion 226, and the second ceiling portion 228 may define a processing space 300. The processing space 300 may include the inner space of the lower chamber 104 and the inner space of the upper chamber 102. The chamber 100 may surround the processing space 300, and the processing space 300 may not be connected to an external environment. Therefore, the processing space 300 of the chamber 100 may be in a vacuum environment when the measurement system operates.

The multi-electron beam generator 108 configured to generate the electron beams 158a to 158d may be coupled with the chamber 100. In more detail, a lower portion of the multi-electron beam generator 108 may be coupled with the second ceiling portion 228 of the upper chamber 102. An upper portion of the multi-electron beam generator 108 may be placed outside the upper chamber 102. The electron beams 158a to 158d may be irradiated into the upper chamber 102 from the lower portion of the multi-electron beam generator 108. In some embodiments, different from the measurement system 1000 shown in FIG. 1, the multi-electron beam generator 108 may be placed inside the upper chamber 102.

The multi-electron beam generator 108 may include an electron gun 150 and a split plate 152. The electron gun 150 may generate a bulk electron beam 156. The electron gun 150 may include a filament and an anode, which are arranged therein. According to an embodiment, the filament may be used as a cathode. The filament may include a metal material, such as tungsten (W), tantalum (Ta), or molybdenum (Mo). When the filament is exposed to a high temperature, electrons bound to a surface of the filament may break free from the binding force of atomic nuclei and escape. The anode may accelerate the escaped electrons, however, the present disclosure should not be limited thereto or thereby. The electron gun 150 may generate the bulk electron beam 156 in a different way.

The generated bulk electron beam 156 may be irradiated onto the split plate 152. The split plate 152 may be provided with a plurality of apertures 154 defined therethrough. As shown in FIG. 4, four apertures 154 may be defined, however, the present disclosure is not limited thereto. In some embodiments, the number of the apertures 154 may be two, three, or five or more. The split plate 152 may split the bulk electron beam 156 into a plurality of electron beams 158a to 158d through the apertures 154. According to an embodiment, the split plate 152 may split the bulk electron beam 156 into the electron beams 158a to 158d in different ways.

The electron beam column 110 may be coupled with a lower end of the multi-electron beam generator 108. The electron beams 158a to 158d generated by the split plate 152 may be irradiated to the electron beam column 110. The electron beam column 110 may guide the electron beams 158a to 158d.

In more detail, the electron beam column 110 may include at least one macro lens 160 configured to guide the electron beams. As an example, the macro lens 160 may be an electromagnetic lens. The electromagnetic lens may be formed by a cylindrical electromagnet wound with a coil. The electromagnetic lens may gather the electrons into a focal point or narrow the electron beam by utilizing the property of electrons being bent by a magnetic field, however, the present disclosure should not be limited thereto or thereby. The macro lens 160 may be another type of lens that gathers the electrons or narrows the electron beam in a different way.

In the present disclosure, the electron beam column 110 including one macro lens 160 is shown as a representative example, however, the present disclosure should not be limited thereto or thereby. The electron beam column 110 may include a plurality of macro lenses 160 that overlap each other vertically to guide the electron beams 158a to 158d, and the number of the macro lenses 160 should not be particularly limited. As an example, the electron beam column 110 may include two macro lenses 160. At least one of the two macro lenses 160 may gather the plural electron beams 158a to 158d and may narrow the plural electron beams 158. The other macro lens of the two macro lenses 160 may be placed close to the inspection target to determine a size of the plural electron beams 158a to 158d being irradiated.

In addition, the electron beam column 110 may include a plurality of micro-lenses 162a to 162d each configured to control irradiation points of the electron beams 158a to 158d. The irradiation points may be areas where the electron beams 158a to 158d reach the surface of the inspection target. The micro-lenses 12 may correspond to the electron beams 158a to 158d, respectively. The micro-lenses 162a to 162d may control the corresponding electron beams 158a to 158d to irradiate different points, respectively. Further, the micro-lenses 162a to 162d may rotate the irradiation points of the corresponding electron beams 158. In more detail, the micro-lenses 162a to 162d may allow the irradiation points of the corresponding electron beams 158a to 158d to move along a circular trajectory. In addition, in some embodiments, the micro-lenses 162a to 162d may be selected to be lenses that prevent the corresponding electron beams 158a to 158d from passing through the micro-lenses 162a to 162d, or micro-lenses 162a to 162d may be formed on a plate, connected to common support structures, or otherwise connected to maintain a constant positional relationship with respect to each other, so that the micro-lens structure allows electron beams 158a to 158d to pass therethrough and be focused when the electron beams 158a to 158d align with the micro-lenses 162a to 162d, but blocks or prevents corresponding electron beams 158a to 158d from passing therethrough and/or being focused when the electron beams 158a to 158d are not aligned with the micro-lenses 162a to 162d. In addition, in some embodiments, the micro-lenses 162a to 162d may be controlled to control the electron beams 158a to 158d to not reach or be focused on the nano-probes 118a to 118d even when the electron beams pass through the micro-lenses 162a to 162d. In this case, the electron beams 158a to 158d may be radiated to be at a location or to have a focus at a position spaced apart from the nano probes 118a to 118d by micro-lenses 162a to 162d. Accordingly, no current may flow through the nano probes 118a to 118d.

As an example, the micro-lenses 162a to 162d may be electromagnetic lenses. The micro-lenses 162a to 162d may be placed below the at least one macro lens 160. For instance, in the case where the electron beam column 110 includes plural macro lenses 160, the micro-lenses 162a to 162d may be placed below the macro lens 160 disposed at the lowest level among the macro lenses 160.

The nano-probes 118a to 118d may be placed in the lower chamber 104. In more detail, the nano-probes 118a to 118d may be placed below the electron beam column 110 in the lower chamber 104. In the present disclosure, the measurement system 1000 including four nano-probes 118a to 118d is shown as a representative example, however, the present disclosure is not limited thereto. In some embodiments, the number of the nano-probes 118a to 118d may be two, three, or five or more. Each of the nano-probes 118a to 118d may include a probe arm 114a to 114d and a probe pin 116a to 116d connected to one end of the probe arm 114a to 114d.

Upper ends of the probe arms 114a to 114d may be coupled to the first ceiling portion 224, and more specifically, to a portion of the first ceiling portion 224 adjacent to the opening 106. As shown in FIGS. 1 and 2, each of the probe arms 114a to 114d may include a portion that has a narrower width than the portion coupled to the first ceiling portion 224, and the probe pin 116a to 116d may be connected to one end of the portion having the narrower width. The probe arms 114a to 114d may move the probe pins 116a to 116d horizontally and vertically. The probe arms 114a to 114d may include micro-manipulators, respectively. Each of the micro-manipulators may include a driver and a moving platform. Each driver may provide power to a respective micro-manipulator. Each of the moving platforms may guide the movement of the probe arm 114a to 114d. The probe arms 114a to 114d may move by a distance ranging from nanometers to several tens of micrometers.

The probe pins 116a to 116d may be placed below the electron beam column 110. In more detail, the probe pins 116a to 116d may be placed within a range where the electron beams 158a to 158d are radiated. The probe pins 116a to 116d may include or be formed of a. electrically and/or thermally conductive material, such as tungsten (W), platinum (Pt), gold (Au), diamond (C) and/or a carbon nanotube. As shown in FIG. 1, the probe pins 116a to 116d may have a shape that is bent downward, for example, to include a first portion extending in one direction, such as horizontally, and a second portion extending in a sloped direction (e.g., downward-sloped) compared to a horizontal plane. A bending angle of each of the probe pins 116a to 116d may not exceed about 90°, and may be an angle between, for example, 10° and 90°. Each of the probe pins 116a to 116d may have a shape that becomes narrower toward its tip, and the tip may be referred to as a probe tip 210 in the present disclosure. Each probe tip 210 may have a diameter ranging from several tens of nanometers (nm) (e.g., at its terminal end) to several tens of micrometers (μm) (e.g., at an end that connects to the remainder of the probe pin). The diameter described herein is used to describe a maximum width in a direction perpendicular to an extension direction of the probe 116 or probe tip 210, and is not intended to imply that the probe is necessarily circular in shape. Each probe 116 may have flattened shape, circular shape, or other shape.

The source measure device 126 may be placed outside the chamber 100. The source measure device 126 may be electrically connected to the nano-probes 118a to 118d. The source measure device 126 may measure a current flowing through each of the probe pins 116a to 116d. In addition, the source measure device 126 may apply a voltage to each of the probe pins 116a to 116d. As an example, the source measure device 126 may include hardware and software configured to measure voltage and/or current in each of the probe pins. For example, the source measure device 126 may include a voltage source, a measuring device, a first processor, a first display device, and a first storage device to perform these functions. The voltage source may output a certain voltage. The source measure device 126 may apply the voltage to each of the probe pins 116a to 116d using the voltage source. The measuring device may measure the output voltages and the currents flowing through the probe pins 116a to 116d. The first processor may control the voltage source and the measuring device. In addition, the first processor in combination with the first storage device or another memory device may store the measured current values. Further, the first processor may cause the output voltages and the measured currents to be displayed in real time on the first display device. Programs for performing these functions may be stored in the first storage device. According to an embodiment, the first display device may be omitted. According to an embodiment, the source measure device 126 may utilize a display device of the control system 128.

The control system 128 may be placed outside the chamber 100. The control system 128 may be electrically connected to the source measure device 126. The control system 128 may calculate the position of each of the probe pins 116a to 116d. In more detail, the control system 128 may calculate the positions of the probe tips 210 of the probe pins 116a to 116d. The control system 128 may include a second processor, a second display device, and a second storage device to perform these functions. The second processor may receive the measured currents from the source measure device 126 and may calculate the positions of the probe tips 210 based on the measured currents. The second processor may cause the calculated positions to be displayed in real time on the display device (e.g., as they are determined). Programs for performing these functions may be stored in the second storage device. Each of the first processor and second processor may be a processor (i.e., a hardware circuit), such as a microprocessor, a CPU (Central Processing Unit), a GPU (graphics processor), a digital signal processor (DSP), a field-programmable gate array (FPGA), etc., and may be part of a computer. Such a processor may be formed by several interconnected controllers or processors and may be configured by software, and may be a controller.

The electron detector 112 may be placed in the chamber 100. As an example, referring to FIG. 1, the electron detector 112 may be coupled with the second wall portion 226. The electron detector 112 may detect secondary electrons 180 emitted from the inspection target by the electron beams 158a to 158d. As an example, the electron detector 112 may be electrically connected to the control system 128. The second processor of the control system 128 may analyze data of the detected secondary electrons 180 and may obtain an image of the surface of the inspection target. In addition, the second processor may cause the obtained image to be displayed on the second display device. Programs for performing these functions may be stored in the second storage device. In some embodiments, as shown in FIG. 7, the electron beams 158a 158d may be radiated onto the inspection target, rather than the probe pins 116a to 116d. In this case, secondary electrons 180 may be emitted from the surface of the inspection target, and the electron detector 112 may detect the emitted secondary electrons. An image of the inspection target may be implemented from the secondary electrons 180 detected by the electron detector 112. This is an auxiliary function of the measurement system 1000 to improve workability.

Referring again to FIGS. 1 to 8, the moving stage 124 and the chuck 122 may be disposed on the first bottom portion 220. The chuck 122 may accommodate a substrate 120 including the inspection target. The chuck 122 may be an electrostatic chuck (ESC). The electrostatic chuck may hold and support the substrate 120 using an electrostatic force. The moving stage 124 may be placed under the chuck 122 and may move the chuck 122. The moving stage 124 may move the chuck 122 to allow the inspection target to overlap the electron beam column 110 and the probe pins 116a to 116d of the nano-probes 118a to 118d vertically.

The nano-probes 118a to 118d and the source measure device 126 may measure electrical characteristics of the inspection target. In some embodiments, the inspection target may be a component of a semiconductor device. As an example, the inspection target may be a field effect transistor, a diode, and/or a metal wiring of the semiconductor device. The nano-probes 118a to 118d and the source measure device 126 may measure voltage-current characteristics, a threshold voltage, and/or a leakage current of the transistor. The nano-probes 118a to 118d and the source measure device 126 may measure a forward current, a reverse current, and/or a breakdown voltage of the diode. In addition, the nano-probes 118a to 118d and the source measure device 126 may measure a resistance of the metal wiring, current-voltage characteristics of the metal wiring, a short circuit between the metal wirings, and/or an open circuit between the metal wirings, however, the present disclosure should not be limited thereto or thereby. The nano-probes 118a to 118d may measure electrical characteristics of other components of the semiconductor device.

The probe pins 116a to 116d of the nano-probes 118a to 118d may be in contact with the probing points of the inspection target. As an example, the probing points may be a gate contact, a source contact, and a drain contact of MOS field-effect transistors as shown in FIG. 8. Each of the probe pins 116a to 116d may transmit a voltage of the source measure device 126 to the inspection target through the contact. In addition, the probe pins 116a to 116d may transmit currents flowing through the inspection target to the measuring device of the source measure device 126 through the contacts.

The probe tips 210 of the probe pins 116a to 116d may be required to be precisely in contact with the probing points of the inspection target to allow the nano-probes 118a to 118d to measure electrical characteristics of the inspection target.

The micro-lenses 162a to 162d may control the irradiation points of the electron beams 158a to 158d, respectively. Then, the source measure device 126 may measure a current generated in each of the probe pins 116a to 116d when the electron beams 158a to 158d are irradiated to the probe pins 116a to 116d. The control system 128 may calculate the position of each of the probe tips 210 based on the generated currents. The probe pin 116a to 116d may have a shape that tapers toward the probe tip 210. Therefore, the irradiation area of the electron beam 158a to 158d may vary depending on positions within the probe pin 116a to 116d, and thus, the value of the measured current may vary depending on the positions within the probe pin 116a to 116d. The irradiation area may be an area in the probe pin 116a to 116d onto which the electron beam 158a to 158d is irradiated. The values of the currents generated at the positions where the electron beam 158a to 158d is irradiated in the probe pin 116a to 116d may be defined as reference values for each position. The process of measuring the reference values for each position may include scanning the probe pin 116a to 116d using the electron beam to measure the current values for each position of the probe pin 116a to 116d. Consequently, when the electron beam 158a to 158d is irradiated onto the probe pin 116a to 116d, the current may be generated in the probe pin 116a to 116d, and the location where the electron beam 158a to 158d is irradiated within the probe pin 116a to 116d may be calculated by comparing the generated current with the reference values for each position. Then, the position of the probe tip 210 may be derived from the calculated positions. The reference values for each position may be obtained each time a probe pin 116a to 116d is replaced. According to an embodiment, considering that the probe pin 116a to 116d wears out when in contact with the probing point, the reference values for each position may be reacquired after using the probe pin 116a to 116d for a certain number of times.

As shown in FIG. 5, at least one of the micro-lenses 162a to 162d may rotate the irradiation point of the corresponding electron beam 158a to 158d, for example, by a rotation coupled with tilting in order to move rotate the irradiation point along a shape such as a circle. For example, the irradiation points of the electron beams 158a to 158d may be changed by physically tilting the micro-lenses 162a to 162d. Alternatively, the micro-lenses 162a to 162d may include a deflector. In this case, the lenses of the micro-lenses 162a to 162d may be fixed, and the deflector may control the deflection of the electron beams 158a to 158d. In some embodiments, the deflector may deflect the beam by electronically controlling the beam using electrodes or coils. For example, the electron beam 158a to 158d corresponding to each of the at least one micro-lens 162a to 162d may move along a circular trajectory 170 while being radiated. Each of the probe pins 116a to 116d may generate the current at a time point where each of the probe pins 116a to 116d overlaps the irradiation point of the respective rotating electron beam 158a to 158d. The source measure device 126 may measure the generated currents. The control system 128 may calculate the position of each of the probe pins 116a to 116d based on the measured currents and the positions of the irradiation points of the electron beams 158a to 158d. Each of the probe pins 116a to 116d have a diameter that decreases as it approaches the probe tip. Furthermore, each of the electron beams 158a to 158d may be irradiated onto a corresponding probe pin 116a to 116d, and a current may be generated in the area of the irradiated probe pin. The value of the current may vary depending on the area of the irradiated region. For example, when the electron beam irradiates a location where the diameter of the probe pin is wide, a relatively large current may flow, and when the electron beam irradiates a location where the diameter of the probe pin is narrow, a relatively small current may flow. Accordingly, the position on the irradiated probe pin may be calculated based on the amount of the current.

The electron beams 158a to 158d may be irradiated onto the calculated positions through the micro-lenses 162a to 162d, respectively. For example, the electron beams 158a to 158d may be irradiated onto the probe pins 116a to 116d through the micro-lenses 162a to 162d, respectively, as shown in FIG. 6. Accordingly, the current may be generated from each of the probe pins 116a to 116d. The source measure device 126 may measure the generated currents. The control system 128 may calculate the position of each of the probe tips 210 based on the measured currents.

According to the above-described embodiments, the electron beams 158a to 158d may be irradiated to the probe pins 116a to 116d through the micro-lenses 162a to 162d, respectively. More specifically, an irradiation point of one of the electron beams 158a to 158d may be rotated, tracing a circular trajectory. Accordingly, the approximate positions of the probe pins 116a to 116d may be calculated. Subsequently, the electron beams 158a to 158d may be individually radiated onto the calculated positions of the probe pins 116a to 116d. Alternatively, the step of rotating the irradiation point of the one electron beam may be omitted. In this case, the electron beams may be radiated onto arbitrary positions and may be moved along X and Y axes. At this time, while monitoring the current values of the probe pins 116a to 116d, points where the electron beams 158a to 158d and the probe pins 116a to 116d vertically overlap may be found. Accordingly, the current may be generated in each of the probe pins 116a to 116d, and the source measure device 126 may measure the generated currents. In addition, the control system 128 may calculate the positions of the probe tips 210 of the probe pins 116a to 116d based on the currents measured by the source measure device 126. Accordingly, the probe tips 210 may be precisely positioned at the probing points within the inspection target. More specifically, the separation distances between each of the calculated positions of the probe tips 210 and corresponding the probing point may be calculated. From the calculated separation distances, the X-axis distance and the Y-axis distance by which the probe tips 210 must be moved may be calculated.

Further, since the electron beams 158a to 158d respectively correspond to the probe pins 116a to 116d, the source measure device 126 may monitor changes in the current in real time according to the movement of each of the probe pins 116a to 116d. In addition, the control system 128 may calculate the position of each of the probe tips 210 in real time (e.g., all at the same time). Accordingly, defects such as collision between the probe tips 210 may be prevented.

The control system 128 may calculate the position of each of the probe tips 210. Therefore, positioning the probe tips 210 at the probing points may be automated. Accordingly, work efficiency may be improved.

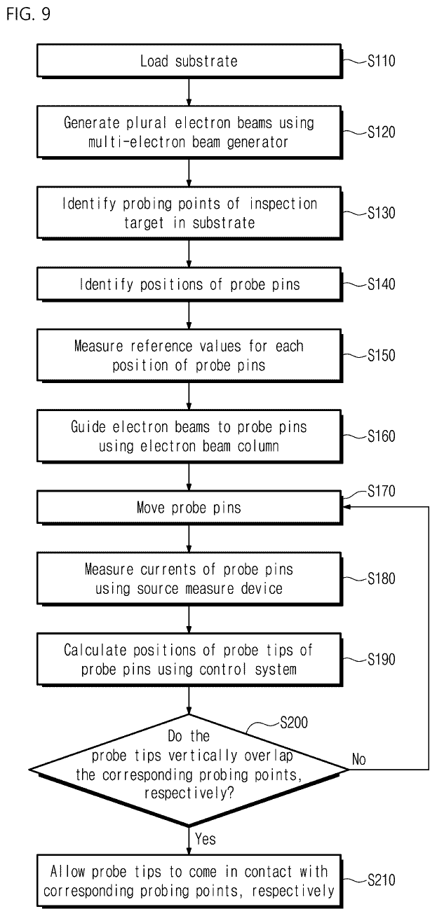

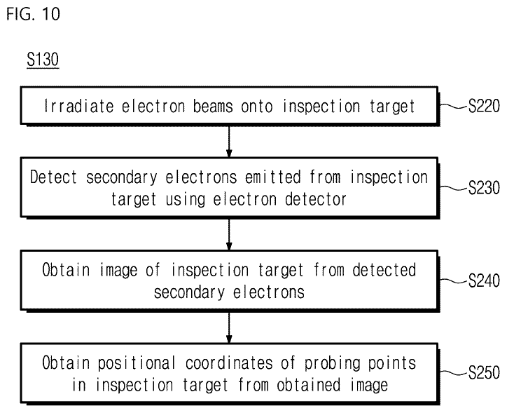

FIG. 9 is a flowchart illustrating a method of operating a measurement system according to an embodiment of the present disclosure. FIG. 10 is a flowchart illustrating an operation (S130) of FIG. 9.

Referring to FIGS. 9 and 10, the method of operating the measurement system 1000 (hereinafter, referred to as an operation method) may include generating the plural electron beams 158a to 158d using the multi-electron beam generator 108 (S120), identifying the positions of the probe pins 116a to 116d (S140), measuring the reference values for each position of the probe pins 116a to 116d (S150), guiding the electron beams 158a to 158d to the probe pins 116a to 116d using the electron beam column 110 (S160), moving the probe pins 116a to 116d (S170), measuring the currents of the probe pins 116a to 116d using the source measure device (S180), calculating the positions of the probe tips 210 of the probe pins 116a to 116d using the control system 128 (S190), comparing the positions of the probe tips 210 to the positions of the corresponding probing points (S200), and allowing the probe tips 210 to come in contact with the probing points, respectively, when the probe tips 210 respectively overlap the corresponding probing points vertically (S210).

According to an embodiment, the operation method may further include loading the substrate 120 (S110) and identifying the probing points of the inspection target in the substrate 120 (S130).

Referring to FIG. 10, the identifying of the probing points of the inspection target in the substrate 120 (S130) may include irradiating the electron beams 158a to 158d to the inspection target (S220), detecting the secondary electrons 180 emitted from the inspection target using the electron detector 112 (S230), obtaining the image of the inspection target from the detected secondary electrons 180 (S240), and obtaining positional coordinates of the probing points in the inspection target from the obtained image (S250).

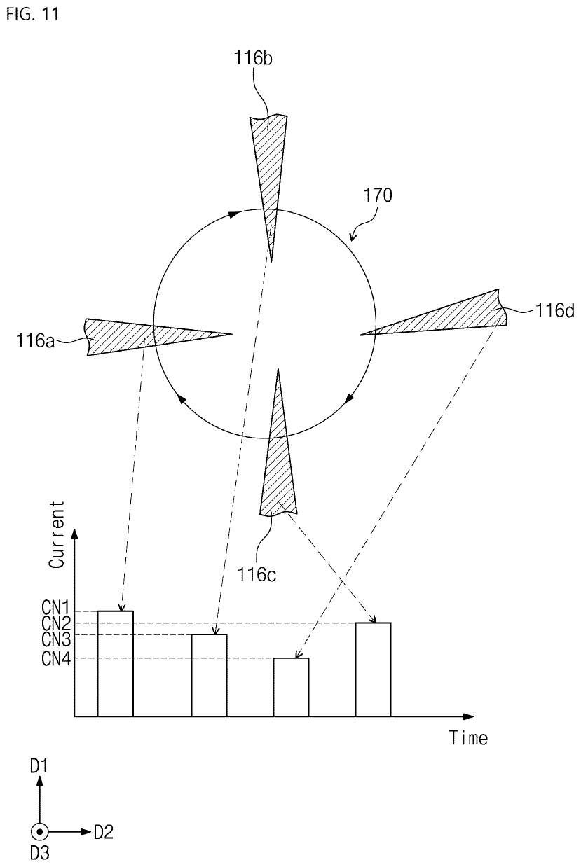

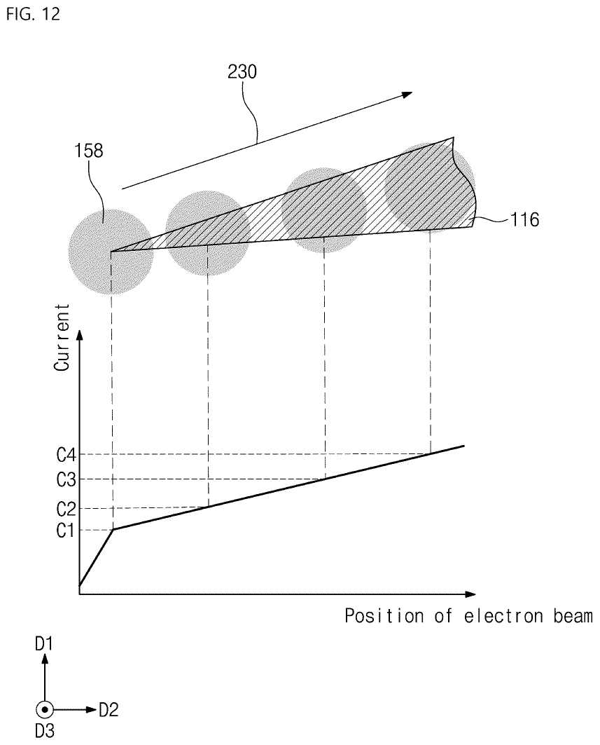

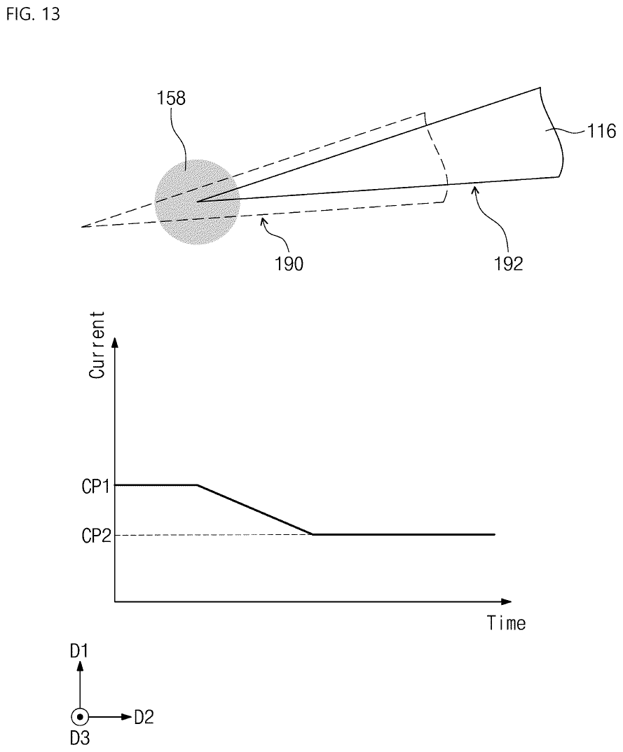

FIG. 11 is a view illustrating the currents flowing through the probe tips when the electron beam is irradiated while rotating according to an embodiment of the present disclosure. FIG. 12 is a view illustrating the reference values for each position of the probe pin according to an embodiment of the present disclosure. FIG. 13 is a view illustrating changes in current as a function of movement of the probe pin according to an embodiment of the present disclosure.

The operation method of the measurement system 1000 will be described in detail with reference to FIGS. 1 and 9 to 13.

The substrate 120 may be loaded (S110). The substrate 120 may be loaded on the chuck 122. The moving stage 124 may allow the inspection target in the loaded substrate 120 to be placed below the electron beam column 110.

The multi-electron beam generator 108 may generate the electron beams 158a to 158d (S120). The multi-electron beam generator 108 may include the electron gun 150 and the split plate 152 through which the apertures 154 are defined. The electron gun 150 may radiate the bulk electron beam 156 to the split plate 152. The bulk electron beam 156 may be split into the plural electron beams 158a to 158d by the apertures 154 of the split plate 152.

The probing points of the inspection target in the substrate 120 may be identified (S130). The operation S130 may include the operations S220, S230, S240, and S250. Hereinafter, the operations S220, S230, S240, and S250 will be described. The electron beams 158a to 158d may be irradiated onto the inspection target. The secondary electrons 180 may be emitted from the surface of the inspection target by the electron beams 158a to 158d. The electron detector 112 may detect the secondary electrons 180. The control system 128 may obtain the image of the inspection target from the data of the detected secondary electrons 180. The control system 128 may obtain the positional coordinates of the probing points in the inspection target from the image.

The positions of the probe pins 116a to 116d may be identified (S140). Each of the probe pins 116a to 116d may be connected to the one end of the probe arm 114a to 114d configured to move the probe pin 116a to 116d horizontally and vertically. The probe arms 114a to 114d may move the probe pins 116a to 116d three-dimensionally. According to an embodiment, to identify the positions of the probe pins 116a to 116d, the electron beam column 110 may guide the irradiation point of the at least one electron beam 158a to 158d to rotate. The electron beam column 110 may include the micro-lenses 162a to 162d, and the electron beam column 110 may guide the irradiation points of the electron beams 158a to 158d using the micro-lenses 162a to 162d, respectively. In this step, according to some embodiments, the irradiation point of at least one of the electron beams 158a to 158d may be rotated, and the remaining electron beams 158a to 158d may be prevented from being radiated or radiating a probe pin. Accordingly current may be generated in each of the probe pins 116a to 116d by the at least one electron beam having the rotating irradiation point. Referring to FIG. 11, the value of the currents generated in the probe pins 116a 116d may be confirmed. Referring to FIG. 11, the current may be generated in each of the probe pins 116a to 116d by the at least one electron beam 158a to 158d. In more detail, when the at least one electron beam 158a to 158d overlaps the probe pins 116a to 116d, the current may be generated in each of the probe pins 116a to 116d. The source measure device 126 may measure the generated currents. The control system 128 may calculate the position of the probe tip 210 of each of the probe pins 116a to 116d based on the measured currents. In some embodiments, the step of rotating the irradiation point of the at least one electron beam may be omitted. In this case, the electron beams 158a to 158d may be concurrently individually irradiated onto arbitrary positions, and by finely moving each of them along the X and Y axes (e.g., by moving a corresponding probe arm), the corresponding probe pins 116a to 116d may be found.

The reference values for each position of the probe pins 116a to 116d may be measured (S150). Referring to FIG. 12, the electron beams 158a to 158d may scan the corresponding probe pins 116a to 116d, respectively. Each of the electron beams 158a to 158d may scan the corresponding probe pin 116a to 116d while moving along a travel path 230 of the electron beam. The values of the currents (e.g., C1 through C4) generated in a particular probe pin 116a to 116d may vary depending on the irradiation area of the probe pin. As an electron beam moves along a longitudinal length of a probe pin, a different current will be produced for the different locations along the longitudinal length. The source measure device 126 may measure the current values for each position of each probe pin of the probe pins 116a to 116d. In the present embodiment, the current values for each position may be the reference values for each position. The control system 128 may store the reference values for each position of each of the probe pins 116a to 116d. According to an embodiment, the operation of measuring the reference values for each position of each of the probe pins 116a to 116d (S150) may be omitted. The operation of measuring the reference values for each position of each of the probe pins 116a to 116d (S150) may be performed when the probe pins 116a to 116d are replaced or when the number of contacts between each of the probe pins 116a to 116d and the corresponding probing point is greater than or equal to a certain threshold.

The electron beam column 110 may guide the electron beams 158a to 158d to the probe pins 116a to 116d, respectively. Referring again to FIG. 6, the electron beam column 110 may guide the irradiation points of the electron beams 158a to 158d to the probe pins 116a to 116d using the micro-lenses 162a to 162d, respectively.

Referring to FIG. 13, the probe pins may move (S170). Then, the source measure device 126 may measure the currents in the probe pins 116a to 116d (S180). The control system 128 may calculate the positions of the probe tips 210 of the probe pins 116a to 116d(S190). Each of the probe pins 116a to 116d may move from a first position 190 to a second position 192. Due to the movement, the irradiation area may decrease as shown in figures. Consequently, the current values measured by the source measure device 126 may decrease. Referring to FIG. 13, a current value CP2 at the second position 192 may be smaller than a current value CP1 at the first position 190. The operations S170, S180, and S190 may be performed in real time.

The control system 128 may compare the positions of the probe tips 210 to the positions of the corresponding probing points (S200). When the probe tips 210 overlap the corresponding probing points vertically, the probe arm 114a to 114d may move vertically to allow the probe tips 210 to come into contact with the corresponding probing points. The operations S170, S180, and S190 may be repeatedly performed until the positions of the probe tips 210 vertically overlap the positions of the corresponding probing points, respectively.

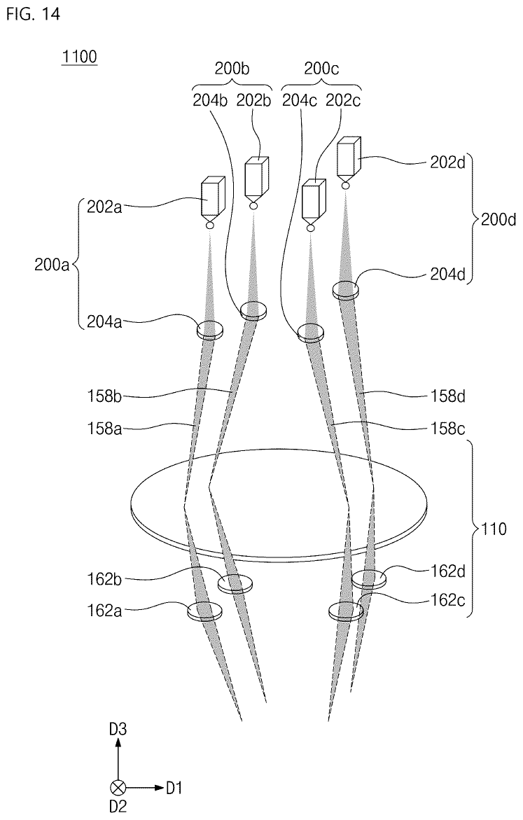

FIG. 14 is a schematic view illustrating a measurement system according to an embodiment of the present disclosure.

Electron beam generators 200a to 200d may generate electron beams 158a to 158d, respectively. Each of the electron beam generators 200a to 200d may include a single electron gun 202a to 202d and an auxiliary lens 204a to 204d. The number of the electron beam generators 200a to 200d may be four as shown in FIG. 14, however, the present disclosure is not limited thereto. In some embodiments, the number of the electron beam generators 200a to 200d may be two, or three or more. Each of the single electron guns 202a to 202d may radiate the electron beam 158a to 158d. The electron beams 158a to 158d may be irradiated to an electron beam column 110 through the auxiliary lenses 204a to 204d, respectively. The auxiliary lenses 204a to 204d may be electromagnetic lenses.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present invention shall be determined according to the attached claims.

What is claimed is:

1. A measurement system comprising:
a chamber;
a multi-electron beam generator coupled with the chamber and configured to generate a plurality of electron beams;
an electron beam column coupled with a lower end of the multi-electron beam generator and configured to guide the electron beams;
nano-probes placed below the electron beam column in the chamber; and
a source measure device electrically connected to the nano-probes, each of the nano-probes comprising:
a probe arm; and
a probe pin connected to one end of the probe arm, wherein the electron beam column and the probe arms are configured to guide the electron beams to the probe pins.

2. The measurement system of claim 1, wherein the source measure device is configured to measure currents generated in the probe pins by the electron beams.

3. The measurement system of claim 2, further comprising a control system configured to calculate positions of the probe pins based on the currents measured by the source measure device.

4. The measurement system of claim 1, wherein the electron beam column comprises:
at least one macro lens configured to guide the electron beams; and
a plurality of micro-lenses configured to control irradiation points of the electron beams, respectively.

5. The measurement system of claim 4, wherein at least one micro-lens among the micro-lenses is configured to rotate a corresponding electron beam among the electron beams.

6. The measurement system of claim 4, configured such that the electron beams are irradiated to the probe pins, respectively, through the micro-lenses to identify positions of the probe pins.

7. The measurement system of claim 1, wherein the chamber comprises a lower chamber and an upper chamber, the upper chamber is disposed on the lower chamber and coupled with a ceiling portion of the lower chamber, and an inner space of the upper chamber is connected to an inner space of the lower chamber through an opening defined through the ceiling portion of the lower chamber.

8. The measurement system of claim 7, wherein upper ends of the probe arms are coupled with the ceiling portion of the lower chamber, and each probe arm is configured to move a respective probe pin horizontally and vertically.

9. The measurement system of claim 1, wherein the multi-electron beam generator comprises:
an electron gun configured to generate a bulk electron beam; and
a split plate configured to split the bulk electron beam into the electron beams, and the split plate is provided with a plurality of apertures defined therethrough.

10. The measurement system of claim 1, wherein the nano-probes and the source measure device are configured to measure electrical characteristics of an inspection target.

11. The measurement system of claim 10, further comprising a controller configured to cause the probe pins to contact probing points of the inspection target, respectively, in order to measure the electrical characteristics of the inspection target, and to cause the source measure device to apply voltages to the probe pins, respectively, and to measure currents of the probe pins.

12. The measurement system of claim 11, wherein the inspection target comprises a field effect transistor, and the probing points comprise a gate contact, a source contact, and a drain contact.

13. The measurement system of claim 11, further comprising:
a chuck configured to hold a substrate comprising the inspection target; and
a moving stage placed under the chuck and configured to move the chuck.

14. The measurement system of claim 11, further comprising an electron detector configured to detect secondary electrons emitted from the inspection target when the electron beams are irradiated to the inspection target.

15. The measurement system of claim 1, wherein the probe pin comprises a conductive material, and the probe pin has a shape that tapers toward a probe tip.

16. A measurement system comprising:
a chamber;
a multi-electron beam generator coupled with the chamber and configured to generate a plurality of electron beams;
an electron beam column coupled with a lower end of the multi-electron beam generator and configured to guide the electron beams, the electron beam column comprising a plurality of micro-lenses configured to control irradiation points of the electron beams, respectively;
nano-probes placed below the electron beam column in the chamber; and
a source measure device electrically connected to the nano-probes, each of the nano-probes comprising:
a probe arm; and
a probe pin connected to one end of the probe arm, wherein the electron beam column and the probe arms are configured to guide the electron beams to the probe pins, and the source measure device is configured to measure currents generated in the probe pins by the electron beams.

17. The measurement system of claim 16, wherein the electron beam column further comprises at least one macro lens disposed between the multi-electron beam generator and the micro-lenses and configured to guide the electron beams.

18. The measurement system of claim 16, further comprising a control system configured to calculate positions of probe tips of the probe pins based on the currents measured by the source measure device.

19. The measurement system of claim 16, further comprising:
a chuck configured to accommodate a substrate; and
an electron detector configured to detect secondary electrons emitted from the substrate when the electron beams irradiate the substrate.

20. A measurement system comprising:
a chamber;
a plurality of electron beam generators coupled with the chamber, configured to generate a plurality of electron beams, respectively, and spaced apart from each other;
an electron beam column coupled with lower ends of the electron beam generators and configured to guide the electron beams;
nano-probes placed below the electron beam column in the chamber; and
a source measure device electrically connected to the nano-probes, each of the nano-probes comprising:
a probe arm; and
a probe pin connected to one end of the probe arm, wherein the electron beam column and the probe arms are configured to guide the electron beams to the probe pins, and the source measure device is configured to measure currents generated in the probe pins by the electron beams.
